(19) United States
(12) Patent Application Publication
(10) Pub. No.: US 2026/0299013 A1
(43) Pub. Date: Oct. 1, 2026

(54) TEST MODE CONTROLLER CIRCUIT CONTROLLING TEST FUNCTIONS FOR CHARGE AND DISCHARGE CONTROLLER CIRCUIT

(71) Applicant: NISSHINBO MICRO DEVICES INC., Tokyo (JP)

(72) Inventor: Takayasu Yoshikawa, Tokyo (JP)

(21) Appl. No.: 19/556,979

(22) Filed: Mar. 4, 2026

(30) Foreign Application Priority Data
Mar. 27, 2025 (JP) 2025-053229
Dec. 16, 2025 (JP) 2025-256516

(51) Int. Cl. G01R 31/28; H02J 7/61; H02J 7/63

(52) U.S. Cl. CPC G01R 31/2879; G01R 31/2856; H02J 7/61; H02J 7/63

(57) ABSTRACT

A test mode control circuit is provided for selectively switching any number of test modes using a single test mode designation signal. The test mode control circuit includes: a first test mode detector circuit detecting a first test mode based on a terminal voltage of a first terminal, and outputting a first test mode detection signal; a second test mode detector circuit detecting a second test mode based on a terminal voltage of a second terminal in response to the first test mode detection signal, and outputting a second test mode detection signal; a test mode latch circuit outputting a test mode latch signal having a predetermined value in response to the second test mode detection signal; and a controller configured to set a predetermined test function corresponding to a value of the test mode latch circuit based on the test mode latch signal.

### CROSS REFERENCE TO RELATED APPLICATION

This application claims benefit of priority to Japanese Patent Applications Nos. 2025-053229 filed Mar. 27, 2025, and 2025-256516 filed Dec. 16, 2025, the entire content of which is incorporated herein by reference.

### TECHNICAL FIELD

The present disclosure relates to a test mode controller circuit and a control method, in an analog semiconductor circuit such as a charge and discharge controller circuit and a low dropout (LDO) regulator circuit, a charge and discharge controller circuit, and a battery apparatus using the charge and discharge controller circuit.

### BACKGROUND ART

Secondary batteries such as lithium-ion batteries are used for portable apparatuses such as smartphones and tablet terminal apparatuses, wearable apparatuses, and battery packs used in apparatuses such as notebook computers. In a secondary battery such as a lithium-ion battery, there is a possibility that heat is generated or battery characteristics are deteriorated when a state such as overcharge, overdischarge, or overcurrent is left. Therefore, it is necessary to monitor a current and a voltage by a controller circuit called a charge and discharge controller circuit or a protection circuit to control charge and discharge so that the battery pack is not brought into a dangerous state.

In recent years, there has been an increasing demand for higher accuracy in detection of various protection functions of a charge and discharge controller circuit.

As a reason for this, for example, when the detection of overcharge or overdischarge is made highly accurate, the battery can be charged or discharged to near the limit, and more power can be extracted from the battery and used. In addition, when the detections of the charge overcurrent and the discharge overcurrent become highly accurate, it is possible to monitor the overcurrent using the shunt resistor having a smaller resistance value, and as a result, it is possible to suppress heat generation even if a large current flows, which can lead to value provision to the user such as shortening of charging time.

In a test process before shipment of a mass production product of a charge and discharge controller circuit, a voltage or a current is applied from an external tester apparatus to each terminal of the charge and discharge controller circuit to confirm operation and detection accuracy of various protection functions. However, when all specifications are inspected one by one with a normal operation specification, the test time becomes enormous. Therefore, the performance measurement or a test is usually shortened using a test mode. In order to realize the demand for high accuracy as described above, it is necessary to perform measurement in more test modes than before in the characteristic matching process and the test process before shipment.

In this case, in the case of a semiconductor circuit having an advanced digital communication function such as I2C or SPI, a method of controlling a register circuit by communication to switch to an arbitrary test mode can be used. However, in such an analog semiconductor circuit such as a charge and discharge controller circuit having no digital communication function, the number of test mode detector circuits increases, and accordingly, the test mode entry method becomes complicated and the test time increases.

A charge and discharge controller circuit according to the prior art has a test mode mainly aimed at shortening a test time, and a method of designating the test mode using various terminals is used (see, for example, Patent Documents 1 to 6).

For example, according to the secondary battery protection IC disclosed in Patent Document 1, it is an object to shorten the time required for a test of an overcharge detection operation in the secondary battery protection IC. Specifically, at the time of testing the overcharge detection operation of the secondary battery protection IC1, in order to increase the frequency of the oscillation circuit, shorten the delay time for the overcharge detection, and shorten the time required for the test, a test controller circuit is provided that increases the value of the constant current that determines the oscillation frequency of the oscillation circuit. The test controller circuit includes each P-channel transistor for additionally connecting two constant currents, and a hysteresis inverter, an inverter, and a NAND gate for performing on-control of each P-channel transistor based on a high-level set value of an overcharge detection output terminal (Cout) and a set value of a V-terminal at a level lower than a ground terminal.

### Patent Documents

Patent Document 1: Japanese Patent No. JP3948435B2
Patent Document 2: Japanese Patent No. JP5344104B1
Patent Document 3: Japanese Patent No. JP4802740B2
Patent Document 4: Japanese Patent No. JP3926718B2
Patent Document 5: Japanese Patent No. JP4392103B2
Patent Document 6: Japanese Patent Laid-open Publication No. JP2012-210139A

### SUMMARY

### Problems to be Solved by the Disclosure

However, in the method of switching the test mode under a single requirement as in the conventional example, when a large number of test modes are required, it is necessary to increase the method of specifying the test mode. Therefore, there is a problem that the number of test mode detector circuits increases and the chip area also increases.

An object of the present disclosure is to provide a test mode controller circuit and method, a charge and discharge controller circuit, and a battery apparatus capable of solving the above problems and selectively switching over and designating an arbitrary number of test modes using one test mode designation signal.

### Solutions to the Problems

According to one aspect of the present disclosure, a test mode controller circuit is provided that includes first and second test mode detector circuits, a test mode latch circuit, and a controller. The first test mode detector circuit detects a first test mode based on a terminal voltage of a first terminal, and outputs a first test mode detection signal, and the second test mode detector circuit detects a second test mode based on a terminal voltage of a second terminal in response to the first test mode detection signal, and outputs a second test mode detection signal. The test mode latch circuit outputs a test mode latch signal having a predetermined value in response to the second test mode detection signal, and the controller is configured to set a predetermined test function corresponding to a value of the test mode latch circuit based on the test mode latch signal.

### Effects of the Disclosure

Therefore, according to the test mode controller circuit of the present disclosure, an arbitrary number of test modes can be selectively switched and designated using one test mode designation signal.

### BRIEF DESCRIPTION OF DRAWINGS

FIG. 1 is a block diagram showing a configuration example of a battery apparatus 100 according to a first embodiment;

FIG. 2 is a block diagram showing a configuration example when a charge and discharge controller circuit 3 of FIG. 1 is tested;

FIG. 3 is a block diagram showing a configuration example of the charge and discharge controller circuit 3 of FIG. 1;

FIG. 4 is a block diagram showing a configuration example of a counter circuit 13 of FIG. 3;

FIG. 5 is a timing chart showing an operation of a counter circuit 13 of FIG. 4;

FIG. 6 is a timing chart showing an operation of the charge and discharge controller circuit 3 of FIG. 3;

FIG. 7 is a block diagram showing a flow of a control signal when the charge and discharge controller circuit 3 of FIG. 3 is tested;

FIG. 8 is a block diagram showing a configuration example of a charge and discharge controller circuit 3A according to a second embodiment;

FIG. 9 is a block diagram showing a flow of a control signal when the charge and discharge controller circuit 3A of FIG. 8 is tested;

FIG. 10 is a block diagram showing a configuration example of a charge and discharge controller circuit 3B according to a third embodiment;

FIG. 11 is a timing chart showing an operation of the charge and discharge controller circuit 3B of FIG. 10;

FIG. 12 is a block diagram showing a flow of a control signal when the charge and discharge controller circuit 3B of FIG. 10 is tested;

FIG. 13 is a block diagram showing a configuration example of a charge and discharge controller circuit 3C according to a fourth embodiment;

FIG. 14 is a timing chart showing the operation of the charge and discharge controller circuit 3C of FIG. 13;

FIG. 15 is a block diagram showing a flow of a control signal when the charge and discharge controller circuit 3C of FIG. 13 is tested;

FIG. 16 is a block diagram showing a configuration example of a charge and discharge controller circuit 3D according to a fifth embodiment;

FIG. 17 is a block diagram showing a configuration example of a shift register circuit 13A of FIG. 16;

FIG. 18 is a timing chart showing an operation of the shift register circuit 13A of FIG. 17;

FIG. 19 is a timing chart showing the operation of the charge and discharge controller circuit 3D of FIG. 16;

FIG. 20 is a block diagram showing a flow of a control signal when the charge and discharge controller circuit 3D of FIG. 16 is tested;

FIG. 21 is a block diagram showing a configuration example of a charge and discharge controller circuit 3E according to a sixth embodiment;

FIG. 22 is a block diagram showing a configuration example of an overcharge detector circuit 12B of FIG. 21;

FIG. 23 is a flowchart showing charge and discharge control processing executed by the charge and discharge controller circuit 3E of FIG. 21;

FIG. 24 is a block diagram showing a configuration example of a test mode controller circuit 20F which is a modified embodiment of the test mode controller circuit 20B of FIG. 10, the test mode controller circuit 20C of FIG. 13, the test mode controller circuit. 20D of FIG. 16, and the test mode controller circuit 20E of FIG. 21; and

FIG. 25 is a block diagram showing a configuration example of an overcharge detector circuit 12D that is a modified embodiment of the overcharge detector circuit 12B of FIG. 22.

### DETAILED DESCRIPTION

Hereinafter, embodiments and modified embodiments according to the present disclosure will be described with reference to the drawings. Note that the same or similar components are denoted by the same reference signs.

### First Embodiment

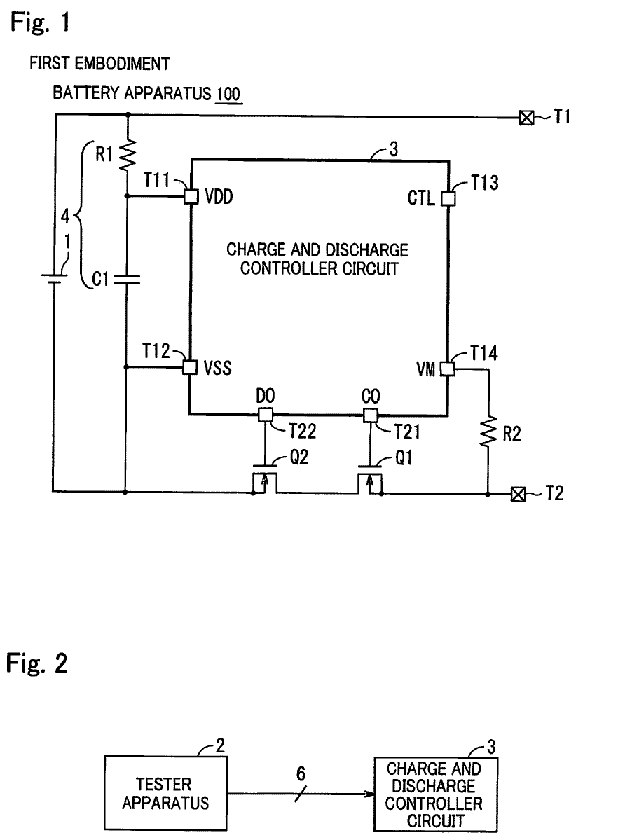

FIG. 1 is a block diagram showing a configuration example of a battery apparatus 100 according to a first embodiment. The configuration of FIG. 1 is also applied to second to sixth embodiments.

Referring to FIG. 1, the battery apparatus 100 includes a secondary battery 1, a charge and discharge controller circuit 3 having terminals T11, T12, T13, T14, T21, and T22, a low-pass filter 4 having a resistor R1 and a capacitor C1, a charge control transistor Q1, a discharge control transistor Q2, and a voltage detection resistor R2. The battery apparatus 100 includes an external positive electrode terminal T1 and an external negative electrode terminal T2 used for charging and discharging the secondary battery 1, and the external positive electrode terminal Tl and the external negative electrode terminal T2 are collectively referred to as “external terminals”. In this case, the load or the charger connected to the terminals T1 and T2 is connected to the secondary battery 1 via the charge and discharge controller circuit 3 to which the charge control transistor Q1 and the discharge control transistor Q2 are connected via the terminals T21 and T22, respectively. In addition, the low-pass filter 4 is connected between the secondary battery 1 and the terminals T11 and T12 of the charge and discharge controller circuit 3. The terminal T13 is a control terminal, and the terminal T14 is a terminal for detecting a terminal voltage of the external negative electrode terminal T2, and is connected to the external negative electrode terminal T2 via the resistor R2. Note that the transistors Q1 and Q2 are configured using, for example, a field effect transistor, and are collectively referred to as a charge and discharge transistor or a charge and discharge switch element.

The protection circuit of the charge and discharge controller circuit 3 has a high-side configuration in which the charge and discharge control transistors Q1 and Q2 are provided between the positive electrode of the secondary battery 1 and the external positive electrode terminal T1, and a low-side configuration in which the charge and discharge control transistors Q1 and Q2 are provided between the negative electrode of the secondary battery 1 and the external negative electrode terminal T2. The present disclosure is applicable to both of these configurations, but an example of the low-side configuration will be described in the present embodiment. That is, in another modified embodiment, the protection circuit may be configured in a high-side configuration.

The charge and discharge controller circuit 3 includes:
(1) a terminal T11 of a power supply voltage VDD connected to the positive electrode of the secondary battery 1;
(2) a terminal T12 of a ground voltage VSS connected to the negative electrode of the secondary battery 1;
(3) a voltage VM detection terminal T14 (in the high-side configuration, the voltage VP detection terminal connected to the external positive electrode terminal T1) connected to the external negative electrode terminal T2;
(4) a CO control terminal T21 connected to the gate of the charge control transistor Q1;
(5) a DO control terminal T22 connected to the gate of the discharge control transistor Q2; and
(6) a control CTL terminal T13 that receives an external input control signal. Note that T11 to T22 are abbreviated as “terminals”.

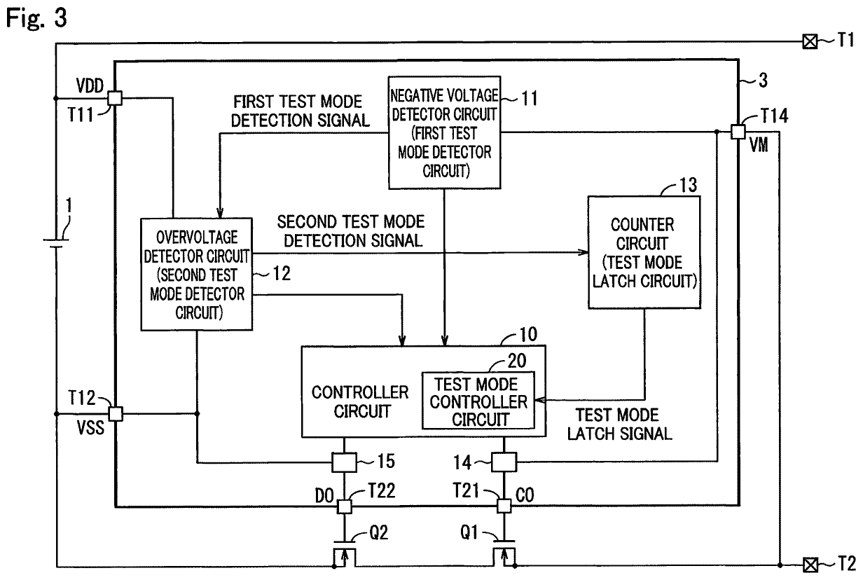

Referring to FIG. 3, the charge and discharge controller circuit 3 includes a negative voltage detector circuit 11, an overvoltage detector circuit 12, a counter circuit 13, a charge controller circuit 14 used as a driver circuit, a discharge controller circuit 15 as a driver circuit, and a controller circuit (an example of a controller) 10 including a test mode controller circuit 20. Note that, in order to turn off the charge control transistor Q1, the VM voltage that is the source voltage of the charge control transistor Q1 needs to be applied to the gate of the charge control transistor Q1 as the low-level output, and thus the reference voltage of the charge controller circuit 14 is connected to the VM terminal T14. In addition, in order to turn off the discharge control transistor Q2, the VSS voltage that is the source voltage of the discharge control transistor Q2 needs to be applied to the gate of the discharge control transistor Q2 as the low-level output, so that the reference voltage of the discharge controller circuit 15 is connected to the VSS terminal T12.

When detecting an abnormal state of the battery voltage such as overcharge or overdischarge based on the power supply voltage VDD voltage, the charge and discharge controller circuit 3 transitions from the normal state to the overcharge protection state or the overdischarge protection state after a predetermined delay time elapses. In this case, in the normal state, the charge and discharge controller circuit 3 outputs a high-level charge control signal and a high-level discharge control signal from the terminal T21 and the terminal T22, respectively, and permits both charge and discharge. In addition, in a protective state in which charging should be prohibited, such as an overcharge protective state, the charge and discharge controller circuit 3 switches the charge control signal from the high level to the low level to turn off the charge control transistor Q1, and prohibits charging of the secondary battery 1 from the charger connected to the terminals T1 and T2. Further, in a protective state in which discharge should be prohibited, such as an overdischarge protective state, the charge and discharge controller circuit 3 switches the discharge control signal from the high level to the low level to turn off the discharge control transistor Q2, so that prohibiting discharge from the secondary battery 1 to the load connected to the terminals T1 and T2.

FIG. 2 is a block diagram showing a configuration example when the charge and discharge controller circuit 3 of FIG. 1 is tested. Note that the configuration of FIG. 2 is also applied to the second to sixth embodiments.

Referring to FIG. 2, the tester apparatus 2 is connected to the terminals T11 to T22 of the charge and discharge controller circuit 3 via six connection lines, and applies a predetermined test voltage or a predetermined test current to the terminals of the charge and discharge controller circuit 3 to control the operation of the charge and discharge controller circuit 3. At this time, the output signals of the terminals T11 to T22 of the charge and discharge controller circuit 3 are measured, and the result of controlling the operation of the charge and discharge controller circuit 3 can be confirmed.

FIG. 3 is a block diagram showing a configuration example of the charge and discharge controller circuit 3 of FIG. 1. Referring to FIG. 3, in the test process before shipment, the operation of the charge and discharge controller circuit 3 is controlled by applying a predetermined test voltage or a predetermined test current to the terminals T11 and T14 of the charge and discharge controller circuit 3 by the external tester apparatus 2 (FIG. 2).

In the test mode according to the first embodiment, a predetermined VM terminal voltage is input from the terminal T14 to the negative voltage detector circuit (first test mode detector circuit) 11, and when the VM terminal voltage is smaller than a predetermined threshold, a first test mode detection requirement is satisfied and a first test mode detection signal is output to the overvoltage detector circuit 12. In the circuits 11 to 13, the circuit name in parentheses indicates the corresponding circuit name for describing the present disclosure. Hereinafter, the same applies to the first to sixth embodiments.

The overvoltage detector circuit (second test mode detector circuit) 12 does not output s second test mode detection signal when not receiving the first test mode detection signal, and outputs the second test mode detection signal when receiving the first test mode detection signal. Therefore, when the VDD terminal voltage is input to the overvoltage detector circuit 12 from the terminal T11 and the VDD terminal voltage is larger than the predetermined threshold, the overvoltage detector circuit 12 outputs the second test mode detection signal when the second test mode detection requirement is satisfied and the first test mode detection signal is received.

Every time receiving the second test mode detection signal, the counter circuit (test mode latch circuit) 13 rewrites latch information held therein, and outputs a test mode latch signal corresponding to the latch information to the test mode controller circuit 20 in the controller circuit 10. In response, the test mode controller circuit 20 enables a test function corresponding to the received test mode latch signal.

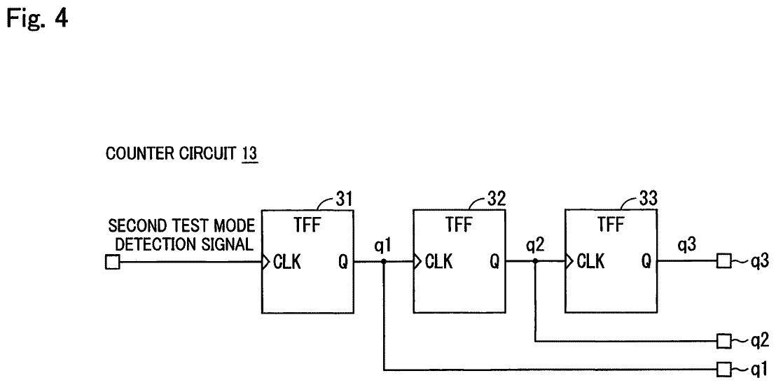

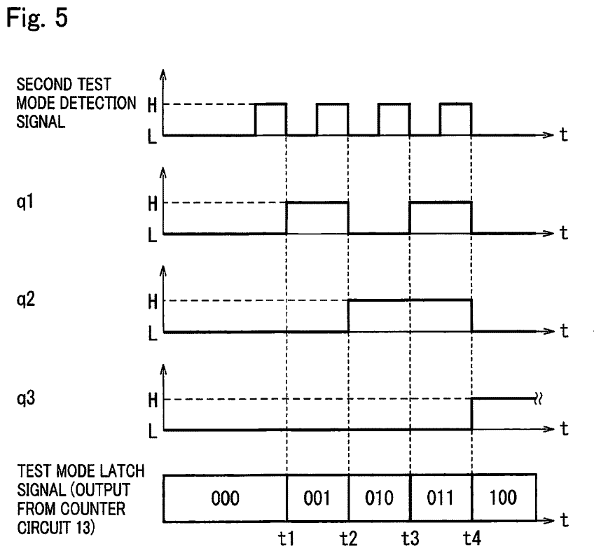

FIG. 4 is a block diagram showing a configuration example of the counter circuit 13 of FIG. 3. FIG. 5 is a timing chart showing the operation of the counter circuit 13 of FIG. 4.

FIGS. 4 and 5 show an example in which the counter circuit outputs a third-bit test mode latch signal, and three toggle flip-flops (TFFs) 31 to 33 are connected in cascade.

Referring to FIG. 5, the high level or low level of each of output voltages q1, q2, and q3 of each of the TFFs 31 to 33 corresponds to the first bit, the second bit, and the third bit of the third-bit test mode latch signal (000). When the second test mode detection signal is input to the TFFs 31 to 33 in the initial state (up to t1) and the second test mode detection signal repeats output and stop (high level and low level) (t1 to t4), the output voltages q1, q2, and q3 are counted up. Although not shown, the TFFs 31 to 33 also include a reset terminal (R), and can initialize the output voltages Q of the three TFFs 31 to 33 to low level in response to input of a predetermined reset signal.

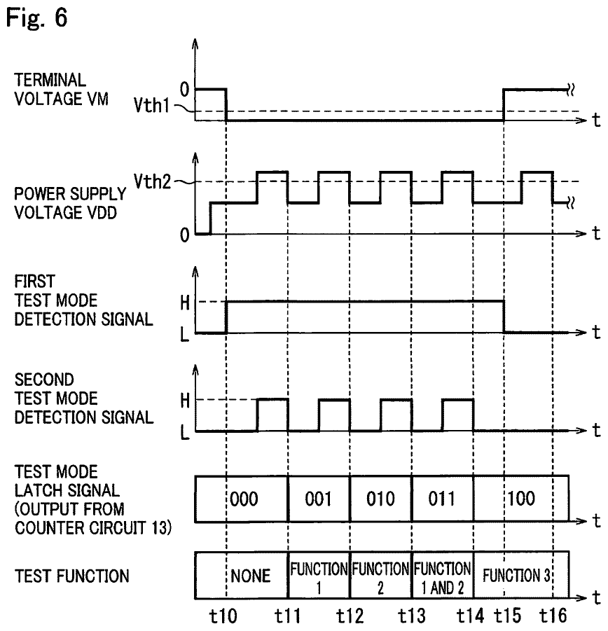

FIG. 6 is a timing chart showing the operation of the charge and discharge controller circuit 3 of FIG. 3.

Referring to FIG. 6, at the timing t10, when a predetermined negative voltage is applied to the terminal T14 and the VM terminal voltage is smaller than a first test mode detection threshold Vth1, the first test mode detection requirement is satisfied, and the negative voltage detector circuit 11 outputs the first test mode detection signal. Next, at the timing t11, when the first overvoltage application to the terminal T11 is performed, the test mode latch signal from the counter circuit 13 is switched, and the corresponding test function is enabled. In the case of FIG. 6, from the timing t12 to the timing t14, the second to fourth overvoltage application to the terminal T11 is performed, the test mode latch signal from the counter circuit 13 is switched, and the corresponding test function is enabled. Further, when the voltage T14 returns to the original voltage at the timing t15, the first test mode detection requirement is not satisfied, and the negative voltage detector circuit 11 stops outputting the first test mode detection signal. Finally, at the timing t16, the overvoltage is applied to the terminal T11, but since the first test mode detection signal is not output, the second test mode detection signal is not output from the overvoltage detector circuit 12, and the test mode latch signal from the counter circuit 13 is not switched.

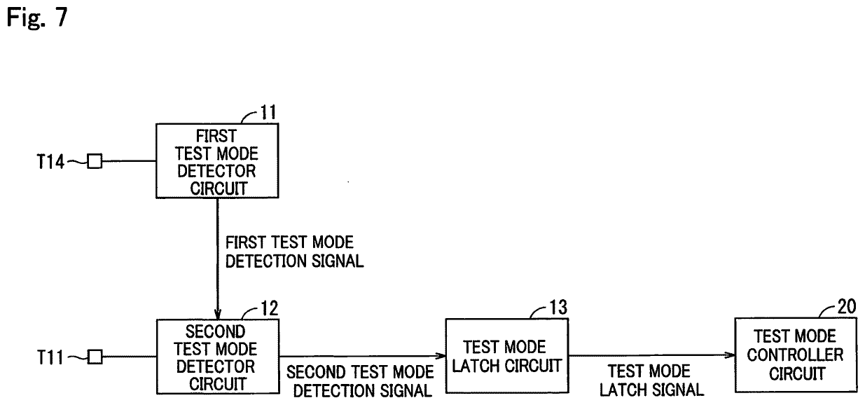

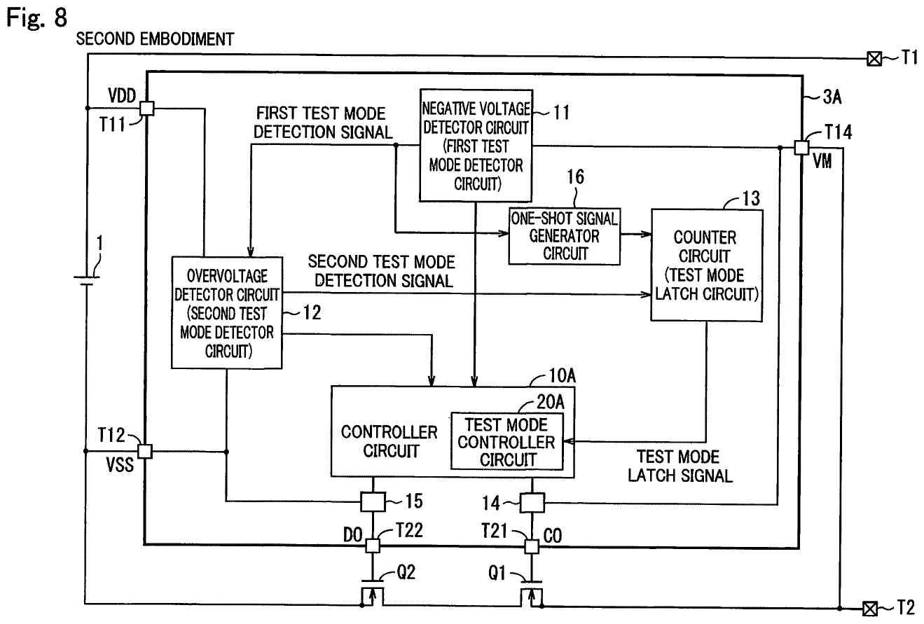

FIG. 7 is a block diagram showing a flow of a control signal when the charge and discharge controller circuit 3 of FIG. 3 is tested. That is, FIG. 7 is a diagram showing only the operation flow in the test mode in the charge and discharge controller circuit 3 of FIG. 3.

Referring to FIG. 7, a first test mode detector circuit 11 receives a predetermined terminal voltage (with reference to the terminal T12) input to a predetermined terminal T14 of the charge and discharge controller circuit 3, which is a semiconductor device, and when the terminal voltage satisfies a predetermined first test mode detection requirement, the first test mode detector circuit 11 outputs the first test mode detection signal. Next, the second test mode detector circuit 12 does not output the second test mode detection signal when not receiving the first test mode detection signal, and outputs the second test mode detection signal when receiving the first test mode detection signal. Therefore, when the terminal voltage input to the terminal T11 of the charge and discharge controller circuit 3, which is a semiconductor device, is input, then the terminal voltage satisfies the predetermined second test mode detection requirement, and the first test mode detection signal is received, the second test mode detector circuit 12 outputs the second test mode detection signal.

Next, every time the second test mode detection signal is received, the test mode latch circuit 13 rewrites latch information held therein, and outputs a test mode latch signal corresponding to the latch information to the test mode controller circuit 20. In response, the test mode controller circuit 20 enables a test function corresponding to the received test mode latch signal. For example, in a case where the test mode latch signal is the third-bit signal 001, the time shortening mode is enabled as an example of the test function in response to the fact that the first-bit signal is 1.

According to the circuit according to the test mode configured as described above, in the normal operation of the charge and discharge controller circuit 3, after the abnormal state is detected, the charge and discharge controller circuit 3 transitions to the protection state after the delay time elapses. However, since the delay time can be shortened in the time shortening mode, the test time can be shortened, and the test cost can be reduced, In addition, for example, in a case where the test mode latch signal is the third-bit signal 010, the internal voltage measurement mode is enabled as an example of another test function in response to the fact that the second-bit signal is one. In the internal voltage measurement mode, a reference voltage or the like inside the circuit, which cannot be measured in the normal state, can be directly measured by outputting the reference voltage or the like to a specific terminal, and the measured value can be used for high accuracy of abnormality detection of the charge and discharge controller circuit 3 and high accuracy of an output voltage of LDO or the like.

### Second Embodiment

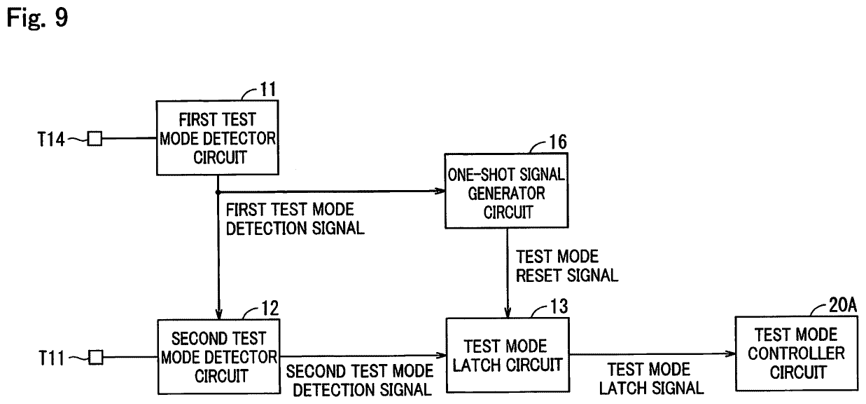

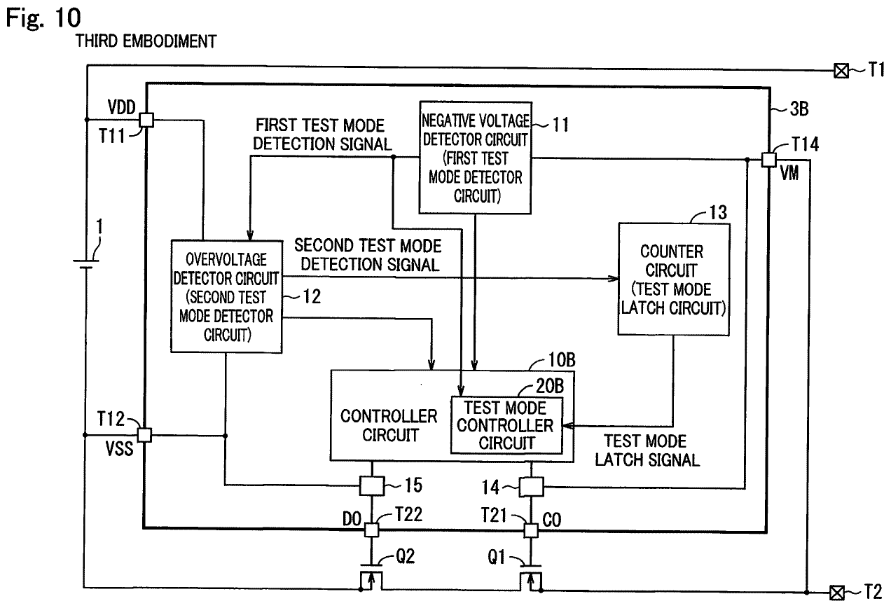

FIG. 8 is a block diagram showing a configuration example of a charge and discharge controller circuit 3A according to a second embodiment. FIG. 9 is a block diagram showing a flow of a control signal when the charge and discharge controller circuit 3A of FIG. 8 is tested.

The charge and discharge controller circuit 3A according to the second embodiment is different from the charge and discharge controller circuit 3 according to the first embodiment in the following points.
(1) A one-shot signal generation circuit 16 is further provided. In this case, the first test mode detection signal from the negative voltage detector circuit 11 is output to the counter circuit 13 via the one-shot signal generation circuit 16,
(2) The controller circuit 10 is replaced with a controller circuit 10A, and the test mode controller circuit 20 is replaced with a test mode controller circuit 20A.

Differences will be described below.

Referring to FIGS. 8 and 9, when receiving the first test mode detection signal from the negative voltage detector circuit 11, the one-shot signal generation circuit 16 outputs a test mode reset signal, which is a one-shot signal output for a predetermined short time, to the counter circuit (test mode latch circuit) 13. When the counter circuit (test mode latch circuit) 13 receives the test mode reset signal, the latch information held therein is initialized, and every time the counter circuit (test mode latch circuit) 13 receives the second test mode detection signal, the counter circuit rewrites the held latch information, and outputs the test mode latch signal corresponding to the latch information to the test mode controller circuit 20A. In response, the test mode controller circuit 20 enables a test. function corresponding to the received test mode latch signal.

According to the second embodiment configured as described above, the same functions and effects as those of the first embodiment are obtained. In addition, since the previously written test mode latch signal is initialized at the timing of starting the test mode switching, it is not necessary to change the input setting procedure of the test mode in consideration of the state of the previous test mode latch signal, so that the test mode operation is facilitated.

### Third Embodiment

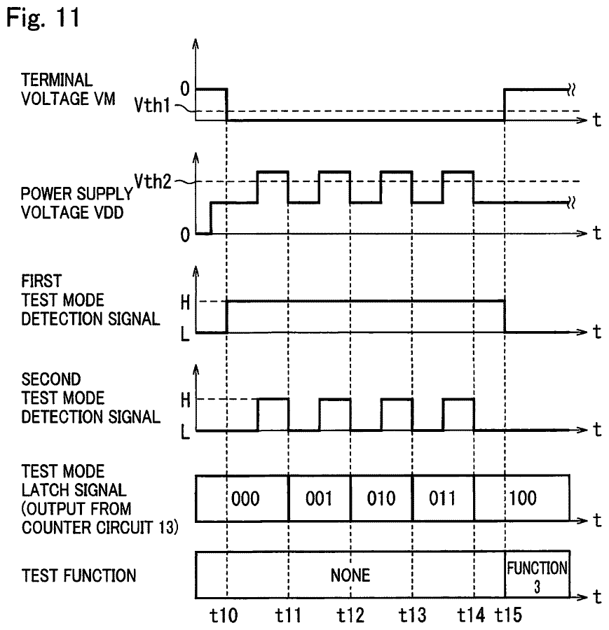

FIG. 10 is a block diagram showing a configuration example of a charge and discharge controller circuit 3B according to a third embodiment. FIG. 11 is a timing chart showing the operation of the charge and discharge controller circuit 3B of FIG. 10. Referring to FIGS. 10 and 11, the charge and discharge controller circuit 3B according to the third embodiment is different from the charge and discharge controller circuit 3 according to the first embodiment in the following points.
(1) A first test mode detection signal from the negative voltage detector circuit 11 is also output to the test mode controller circuit 20B.
(2) The controller circuit 10 is replaced with a controller circuit 10B, and the test mode controller circuit 20 is replaced with a test mode controller circuit 20B.

Differences will be described below.

Referring to FIG. 10, the test mode controller circuit 20B does not enable the test function when receiving the output of the first test mode detection signal, and enables the test function corresponding to the received test mode latch signal when the output of the first test mode detection signal is stopped.

Referring to FIG. 11, when the predetermined negative voltage is applied to the terminal T14 at the timing t10 and the VM terminal voltage is smaller than the first test mode detection threshold Vth1, the first test mode detection requirement is satisfied, and when the negative voltage detector circuit 11 outputs the first test mode detection signal, the overvoltage application to the terminal T11 is performed at the timings t11 to t14, and the test mode latch signal is switched each time. At. this time, since the first test mode detection signal is also output to the test mode controller circuit 20B, the corresponding test function is not enabled. Then, at the timing t15, when the VM terminal voltage returns to the original voltage, the first test mode detection requirement is no longer satisfied, and the negative voltage detector circuit 11 stops the first test mode detection signal. This enables the corresponding test function.

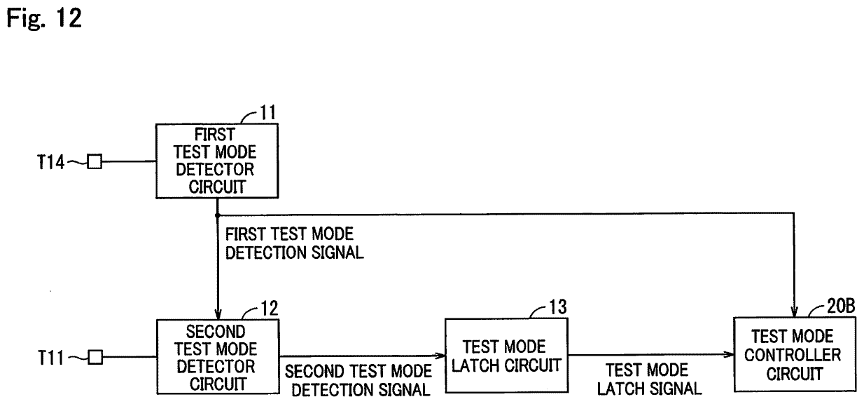

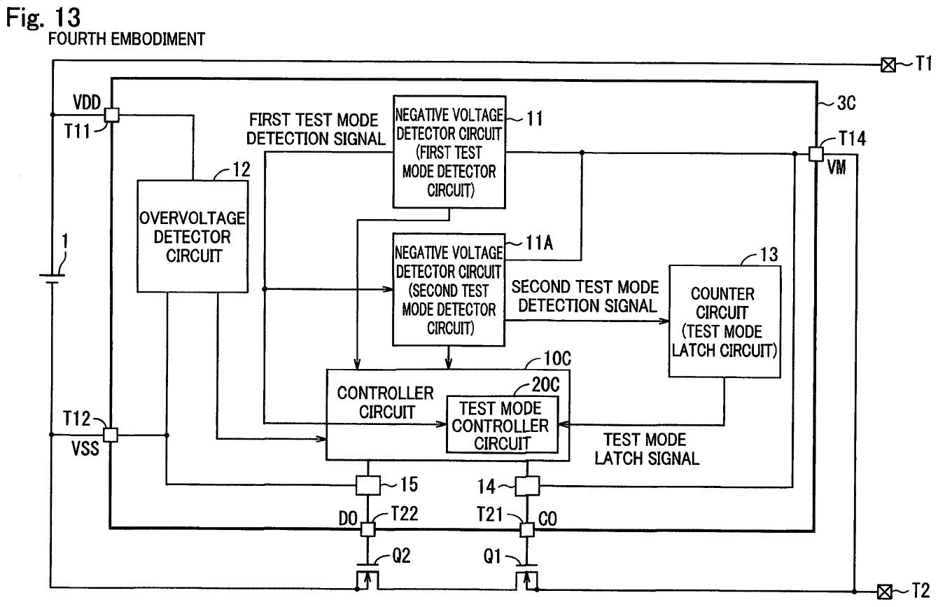

FIG. 12 is a block diagram showing a flow of a control signal when the charge and discharge controller circuit 3B of FIG. 10 is tested. In FIG. 12, the operation is performed as described with reference to FIG. 11.

Referring to FIG. 12, the second test mode detector circuit 12 does not output the second test mode detection signal when not receiving the first test mode detection signal, and outputs the second test mode detection signal when receiving the first test mode detection signal. Therefore, when the predetermined terminal voltage is input to the terminal T14 of the charge and discharge controller circuit 3B, which is a semiconductor device, the terminal voltage satisfies the predetermined second test mode detection requirement, and the first test mode detection signal is received, the second test mode detector circuit 12 outputs the second test mode detection signal. In response to this, every time the second test mode detection signal is received, the test mode latch circuit 13 rewrites latch information held therein, and outputs a test mode latch signal corresponding to the latch information. Further, the test mode controller circuit 20B does not enable the test function when receiving the output of the first test mode detection signal, and enables the test function corresponding to the received test mode latch signal when the output of the first test mode detection signal is stopped.

According to the third embodiment configured as described above, the same functions and effects as those of the first embodiment are obtained. In addition, by performing control such that the test function is enabled after the first test mode detection signal is released, it is possible to avoid occurrence of a malfunction during switching of the latch information of the test mode latch circuit. For example, assuming that the test mode latch signal desired to be finally designated is the third-bit signal 011, when the test mode latch signal enters the state of 010 on the way thereof, the test function such as the internal measurement mode is enabled, the internal voltage of the charge and discharge controller circuit 3 is output to the terminal T11, and it is possible to avoid such a malfunction that becomes unable to satisfy the first test mode detection requirement unintentionally.

### Fourth Embodiment

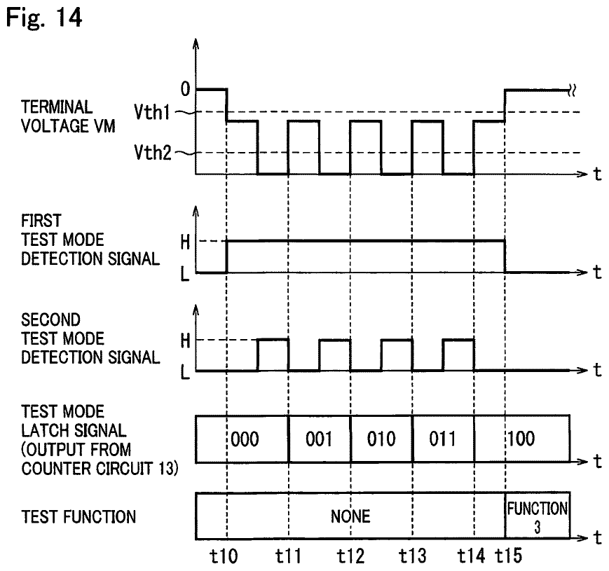

FIG. 13 is a block diagram showing a configuration example of a charge and discharge controller circuit 3C according to the fourth embodiment. FIG. 14 is a timing chart showing the operation of the charge and discharge controller circuit 3C of FIG. 13. The charge and discharge controller circuit 3C according to the fourth embodiment of FIG. 13 is different from the charge and discharge controller circuit 3 according to the first embodiment in the following points.
(1) A negative voltage detector circuit (second test mode detector circuit) 11A is further provided. The overvoltage detector circuit 12 operates only in the normal state and does not operate in the test mode.
(2) The controller circuit. 10 is replaced with a controller circuit 10C, and the test mode controller circuit 20 is replaced with a test mode controller circuit 20C.

Differences will be described below.

Referring to FIGS. 13 and 14, a predetermined VM terminal voltage is input to the negative voltage detector circuit (first test mode detector circuit) 11, and when the VM terminal voltage is smaller than a predetermined threshold voltage Vth1 (see FIG. 14), the first test mode detection requirement is satisfied and a first test mode detection signal is output.

The negative voltage detector circuit (second test mode detector circuit) 11A does not output the second test mode detection signal when not receiving the first test mode detection signal, and outputs the second test mode detection signal to the counter circuit (test mode latch circuit) 13 when receiving the first test mode detection signal. Further, when a predetermined VM terminal voltage is input to the negative voltage detector circuit (second test mode detector circuit) 11A and the VM terminal voltage is smaller than a predetermined threshold voltage Vth2 (<Vth1) (see FIG. 14), the negative voltage detector circuit 11A outputs the second test mode detection signal when the second test mode detection requirement is satisfied and the first test mode detection signal is received. In this case, the threshold voltage Vth1 is, for example, −2 V, and the threshold voltage Vth2 is, for example, −5 V.

Next, every time the counter circuit (test mode latch circuit) 13 receives the second test mode detection signal, the counter circuit (test mode latch circuit) 13 rewrites latch information held therein, and outputs a test mode latch signal corresponding to the latch information. In response, the test mode controller circuit 20C does not enable the test function when receiving the output of the first test mode detection signal, and enables the test function corresponding to the received test mode latch signal when the output of the first test mode detection signal is stopped.

Referring to FIG. 14, when a predetermined negative voltage is applied to the terminal T14 at the timing t10 and the negative voltage is smaller than the first test mode detection threshold, the first test mode detection requirement is satisfied and the first test mode detection signal is output. Then, at the timings t11 to t14, further negative voltage application to the terminal T14 is performed, and the test mode latch signal switches each time, but since the first test mode detection signal is output, the corresponding test function is not enabled. At the timing t15, when the terminal voltage of the terminal T14 returns to the original voltage, the first test mode detection requirement is no longer satisfied, and when the first test mode detection signal is stopped, the corresponding test function is enabled.

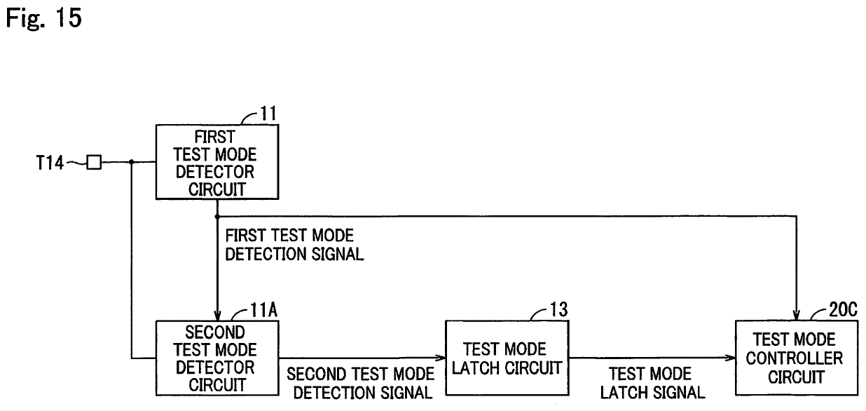

FIG. 15 is a block diagram showing a flow of a control signal when the charge and discharge controller circuit 3C of FIG. 13 is tested. In FIG. 15, as described with reference to FIGS. 13 and 14, the charge and discharge controller circuit 3C operates.

According to the fourth embodiment configured as described above, the same functions and effects as those of the first embodiment are obtained. In this case, in particular, as shown in FIG. 14, after the test function is stopped from the timing t10 to the timing t15, a test function 3 can be executed at the timing t15.

### Fifth Embodiment

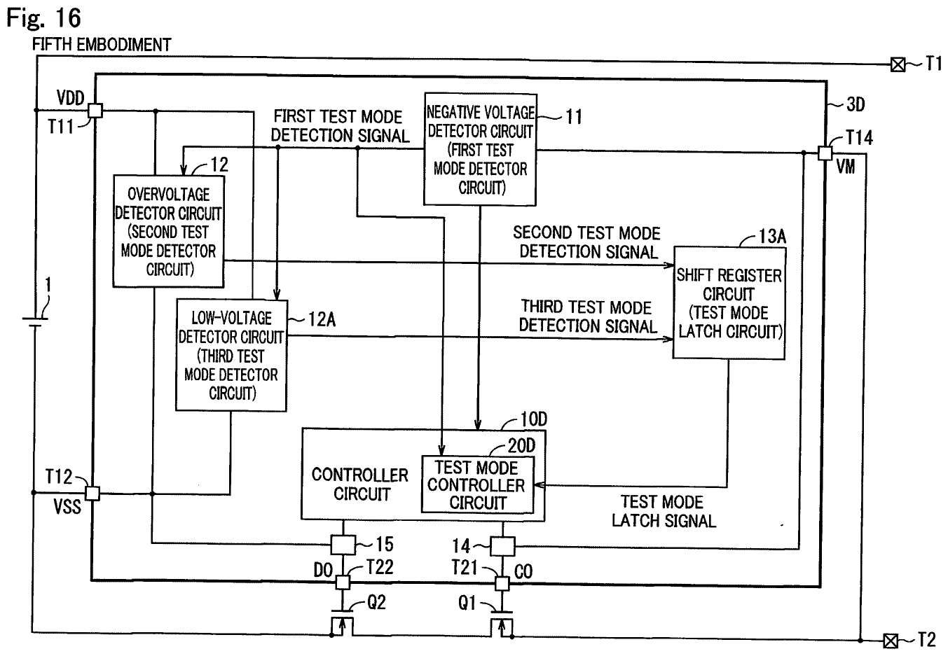

FIG. 16 is a block diagram showing a configuration example of a charge and discharge controller circuit 3D according to a fifth embodiment. In FIG. 16, the charge and discharge controller circuit 3D according to the fifth embodiment is different from the charge and discharge controller circuit 3 according to the first embodiment in the following points.
(1) A low-voltage detector circuit (third test mode detector circuit) 12A is further provided.
(2) A shift register circuit (test mode latch circuit) 13A is provided instead of the counter circuit (test mode latch circuit) 13.
(3) The controller circuit 10 is replaced with a controller circuit 10D, and the test mode controller circuit 20 is replaced with a test mode controller circuit 20D.

Differences will be described below.

Referring to FIG. 16, the low-voltage detector circuit (third test mode detector circuit) 12A does not output the third test mode detection signal when not receiving the first test mode detection signal, and outputs the third test mode detection signal when receiving the first test mode detection signal, Therefore, when the terminal voltage of the predetermined power supply voltage VDD is input from the terminal T11 to the low-voltage detector circuit (third test mode detector circuit) 12A, and the terminal voltage is smaller than the predetermined threshold, the third test mode detection signal is output when the third test mode detection requirement is satisfied and the first test mode detection signal is received. Every time the shift register circuit (test mode latch circuit) 13A receives the second test mode detection signal or the third test mode detection signal, the shift register circuit (test mode latch circuit) 13A rewrites latch information held therein, and outputs a test mode latch signal corresponding to the latch information to the test mode controller circuit 20D. In response, the test mode controller circuit 20D does not enable the test function when receiving the output of the first test mode detection signal, and enables the test function corresponding to the received test mode latch signal when the output of the first test mode detection signal is stopped.

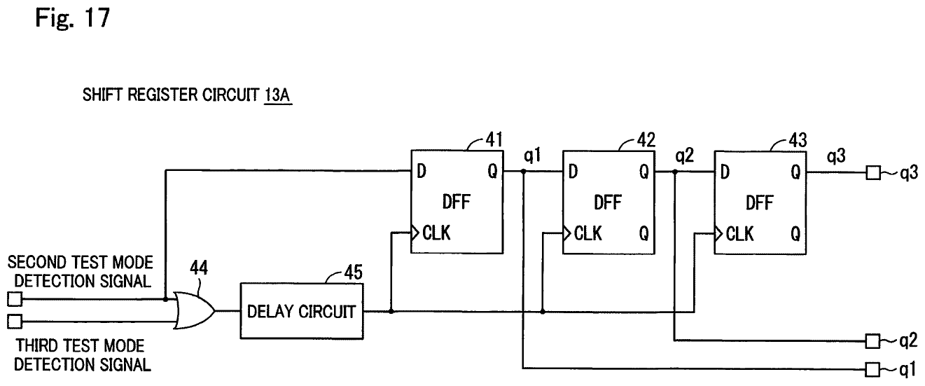

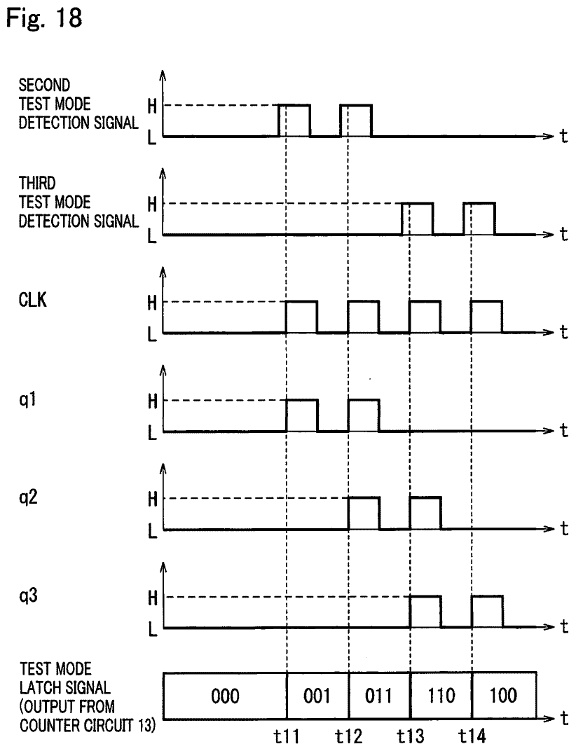

FIG. 17 is a block diagram showing a configuration example of the shift register circuit 13A of FIG. 16. FIG. 18 is a timing chart showing the operation of the shift register circuit 13A of FIG. 17. FIGS. 17 and 18 show an example in which the shift register circuit 13A outputs a third-bit test mode latch signal, and the shift register circuit 13A includes three cascade-connected delay type flip-flops (DFFs) 41 to 43, an OR gate 44, and a delay circuit 45 that delays an input signal by a minute time interval shorter than the time interval corresponding to one clock.

Referring to FIGS. 17 and 18, the high level or the low level of the output voltages q1, q2, and q3 of the DFFs 41 to 43 corresponds to the first bit, the second bit, and the third bit of the third-bit test mode latch signal (000). In this case, when the second test mode detection signal or the third test mode detection signal repeats output and stop (high level and low level), the signal is delayed by the delay circuit 45 and then input as the clock CLK of each of the DFFs 41 to 43, and the output voltages q1, q2, and q3 are shifted and output.

Referring to FIG. 17, the delay circuit 45 is shown assuming a minute delay circuit by an RC circuit, but the present disclosure is not limited thereto, and may be configured to delay by a predetermined delay time using a timer circuit.

Referring to FIG. 17, since the second test mode detection signal is input to the DFF 41, when the shift operation is performed by the second test mode detection signal, the high-level signal is written to the DFF 41 and the output voltage q1 is output. In this case, when the shift operation is performed by the third test mode detection signal, a low-level 0 is written to the DFF 41. Although not shown in FIG. 17, the DFFs 41 to 43 also have a reset terminal (R), and the output voltages of the three DFFs 41 to 43 can be initialized by a predetermined signal input.

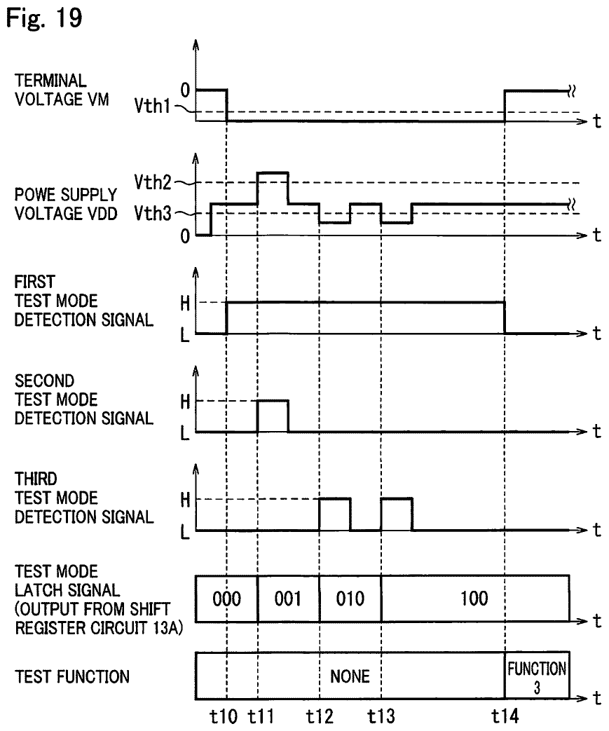

FIG. 19 is a timing chart showing the operation of the charge and discharge controller circuit 3D of FIG. 16.

When a predetermined negative voltage is applied to the terminal T14 at the timing t10 Referring to FIG. 19 and the terminal voltage is smaller than the first test mode detection threshold, the first test mode detection requirement is satisfied, and the negative voltage detector circuit (first test mode detector circuit) 11 outputs the first test mode detection signal. Next, at the timing t11, when a predetermined overvoltage is applied to the terminal T11, since the second test mode detection signal is output from the overvoltage detector circuit (second test mode detector circuit) 12, the high-level signal is written to the DFF 41 of the shift register circuit 13A and a shift operation is performed. At the timings t12 and t13, a predetermined low voltage is applied to the terminal T11, and the third test mode detection signal is output, so that the low-level signal is written to the DFF 41 of the shift register circuit 13A and a shift operation is performed. In this case, even when the test mode latch signal from the shift register circuit (test mode latch circuit) 13A is switched between the timings t11 and t13, since the first test mode detection signal is output, the corresponding test function is not enabled. Further, when the VM terminal voltage of the terminal T14 returns to the original voltage at the timing t14, the first test mode detection requirement is not satisfied, and the first test mode detection signal is stopped, the test mode controller circuit 20D enables the corresponding test function.

As can be seen by comparing the timing charts of FIGS. 11 and 19, by switching the test mode latch signal using the shift register circuit 13A as the test mode latch circuit, an arbitrary test mode latch signal can be selected with a smaller number of times of test mode latch switching as compared with the case of using the counter circuit 13. This effect becomes more pronounced as the number of bits of the test mode latch signal increases. For example, when considering a test mode latch signal of integer N bits, in the embodiment using the counter circuit 13, switching needs to be performed 2^{N-1} times (31 times when N=5) in order to set all bits to 1, but in the embodiment using the shift register circuit 13A, switching only needs to be performed integer N times (5 times when N=5) in order to set all bits to 1.

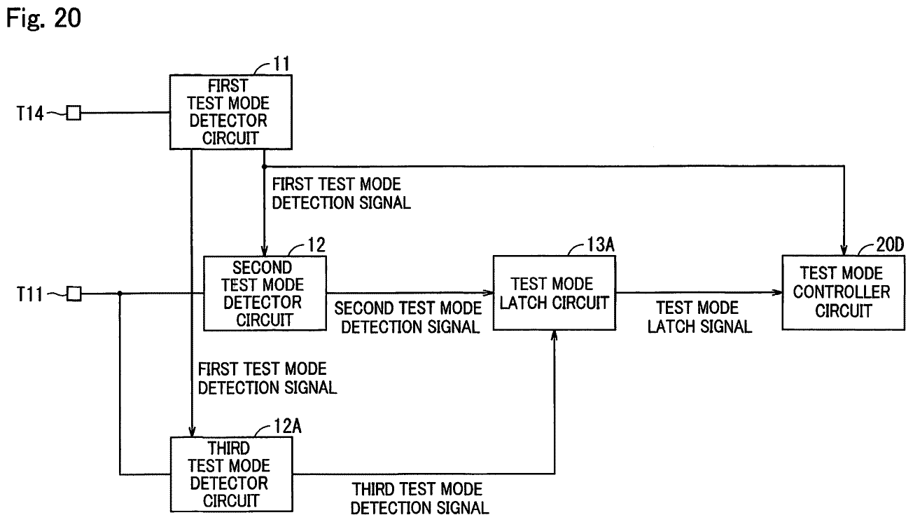

FIG. 20 is a block diagram showing a flow of a control signal when the charge and discharge controller circuit 3D of FIG. 16 is tested.

Referring to FIG. 20, the first test mode detector circuit 11 and the second test mode detector circuit 12 operate in a manner similar to those of the first embodiment. Next, the third test mode detector circuit 12A does not output the third test mode detection signal when not receiving the first test mode detection signal, and outputs the third test mode detection signal to the shift register circuit. (test mode latch circuit) 13A when receiving the first test mode detection signal. Therefore, when a predetermined terminal voltage is input from the terminal T14 of the charge and discharge controller circuit 3, which is a semiconductor device, to the negative voltage detector circuit (first test mode detector circuit) 11, the terminal voltage satisfies a predetermined third test mode detection requirement, and the first test mode detection signal is received, the third test mode detection signal is output. As a result, every time the test mode latch circuit 13A receives the second test mode detection signal or the third test mode detection signal, the test mode latch circuit 13A rewrites latch information held therein, and outputs a test mode latch signal corresponding to the latch information to the test mode controller circuit 20D, In response to this, the test mode controller circuit 20D does not enable the test function when receiving the output of the first test mode detection signal, and enables the test function corresponding to the received test mode latch signal when the output of the first test mode detection signal is stopped.

According to the fifth embodiment configured as described above, the same functions and effects as those of the first embodiment are obtained. In addition to the second test mode detection signal, the test mode of the test mode controller circuit 20D can be controlled using the third test mode detection signal.

### Sixth Embodiment

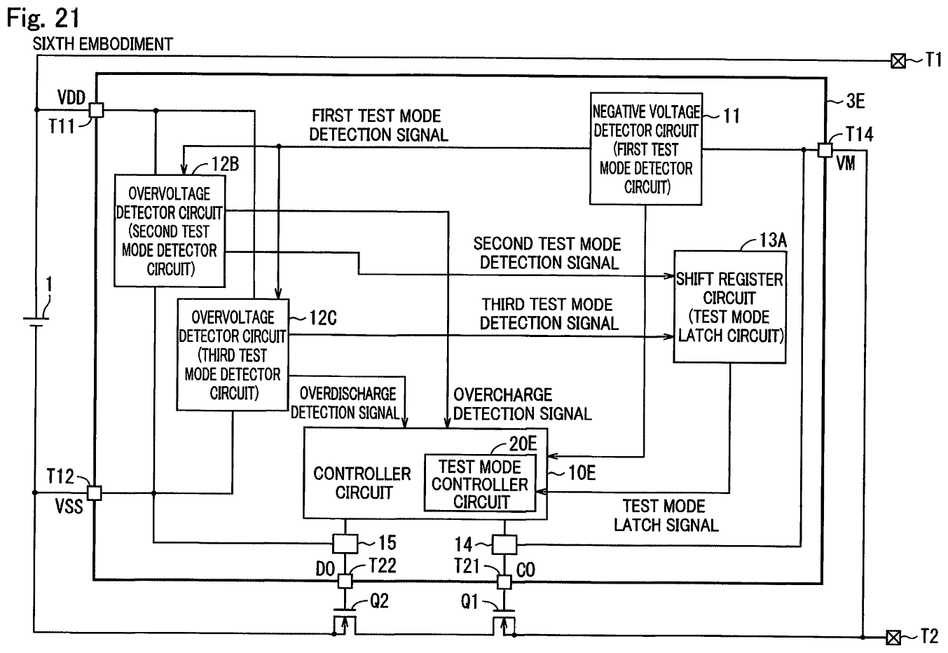

FIG. 21 is a block diagram showing a configuration example of a charge and discharge controller circuit 3E according to a sixth embodiment. In FIG. 21, the charge and discharge controller circuit 3E according to the sixth embodiment is different from the charge and discharge controller circuit 3D according to the fifth embodiment in FIG. 16 in the following points.
(1) An overcharge detector circuit 12B is provided instead of the overvoltage detector circuit 12.
(2) An overdischarge detector circuit 12C is provided instead of the low-voltage detector circuit 12A.
(3) The controller circuit 10D is replaced with a controller circuit 10E, and the test mode controller circuit 20D is replaced with a test mode controller circuit 20E.

Differences will be described below.

Referring to FIG. 21, the negative voltage detector circuit (first test mode detector circuit) 11 operates in a manner similar to that of FIG. 16. When the power supply voltage VDD of the terminal T11 becomes equal to or higher than a predetermined overcharge detection threshold voltage Vth3 and when the first test mode detection signal is not received, the overcharge detector circuit (second test mode detector circuit) 12B outputs the overcharge detection signal to the controller circuit 10E, and does not output the second test mode detection signal to the shift register circuit (test mode detector circuit) 13A. On the other hand, when receiving the first test mode detection signal, the overcharge detector circuit (second test mode detector circuit) 12B outputs the second test mode detection signal to the shift register circuit (test mode latch circuit) 13A, and does not output the overcharge detection signal. In this case, when the power supply voltage VDD voltage of the terminal T11 becomes less than the predetermined overcharge detection threshold value Vth3, the overcharge detector circuit (second test mode detector circuit) 12B stops outputting both of the above two signals, Therefore, when the predetermined power supply voltage VDD terminal voltage is input to the overcharge detector circuit (second test mode detector circuit) 12B and the power supply voltage VDD terminal voltage is equal to or higher than the predetermined overcharge detection threshold voltage Vth3, the overcharge detector circuit (second test mode detector circuit) 12B outputs the second test mode detection signal when the second test mode detection requirement is satisfied and the first test mode detection signal is received.

Further, when the power supply voltage VDD voltage becomes less than a predetermined overdischarge detection threshold voltage Vth4 and the first test mode detection signal is not received, the overdischarge detector circuit (third test mode detector circuit) 12C outputs the overdischarge detection signal to the controller circuit 10E, and does not output the third test mode detection signal. On the other hand, when receiving the first test mode detection signal, the overdischarge detector circuit (third test mode detector circuit) 12C outputs the third test mode detection signal to the shift register circuit (test mode latch circuit) 13A, and does not output the overdischarge detection signal. Then, when the power supply voltage VDD voltage exceeds a predetermined overdischarge detection threshold voltage, both of the two signals stop output. Therefore, when the predetermined power supply voltage VDD is input to the overdischarge detector circuit (third test mode detector circuit) 12C and the voltage is less than the predetermined overdischarge detection threshold voltage, the third test mode detection signal is output when the third test mode detection requirement is satisfied and the first test mode detection signal is received.

When receiving the overcharge detection signal, the controller circuit 10E switches the control signal of the charge control terminal T21 to low level after a predetermined delay time elapses to prohibit the charging of the battery apparatus, and when receiving the overdischarge detection signal, the controller circuit 10E switches the control signal of the discharge control terminal T22 to low level after a predetermined delay time elapses to prohibit the discharging of the battery apparatus. Every time the shift register circuit (test mode latch circuit) 13A receives the second test mode detection signal or the third test mode detection signal, the shift register circuit (test mode latch circuit) 13A rewrites latch information held therein, and outputs a test mode latch signal corresponding to the latch information to the test mode controller circuit 10E.

The test mode controller circuit 20E does not enable the test function when receiving the output of the first test mode detection signal, and enables the test function corresponding to the received test mode latch signal when the output of the first test mode detection signal is stopped.

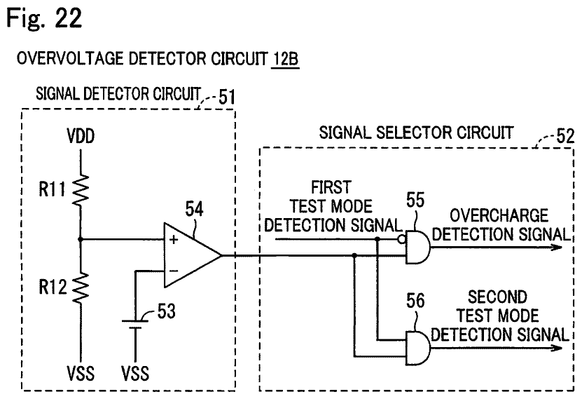

FIG. 22 is a block diagram showing a configuration example of the overcharge detector circuit 12B of FIG. 21.

Referring to FIG. 22, the overcharge detector circuit 12B includes a signal detector circuit 51 and a signal selection circuit 52. In this case, the signal detector circuit 51 has a configuration similar to that of the existing charge and discharge controller circuit, and includes an internal reference voltage source 53, voltage-dividing resistors R11 and R12 that divide the power supply voltage VDD, and a comparator 54 that compares the resistance-divided voltage with the reference voltage of the reference voltage source 53 and outputs a comparison result signal as a detection signal. The signal selection circuit 52 includes two AND gates 55 and 56.

In the signal selection circuit 52, the first test mode detection signal is input to the inverting input terminal of the AND gate 55 and the input terminal of the AND gate 56, and the comparison result signal of the comparator 54 is input to the input terminals of the AND gates 55 and 56. Therefore, the signal selection circuit 52 selects whether to output the detection signal of the comparator 54 as the overcharge detection signal or the second test mode detection signal according to the output state of the first test mode detection signal. That is, when the first test mode detection signal is not output, the detection signal of the comparator is output as the overcharge detection signal. In addition, when the first test mode detection signal is output, the comparison result signal of the comparator 54 is output as the second test mode detection signal.

Note that the overdischarge detector circuit 12C is configured by only interchanging the input terminals of the comparator 54 as compared with the overcharge detector circuit 12B.

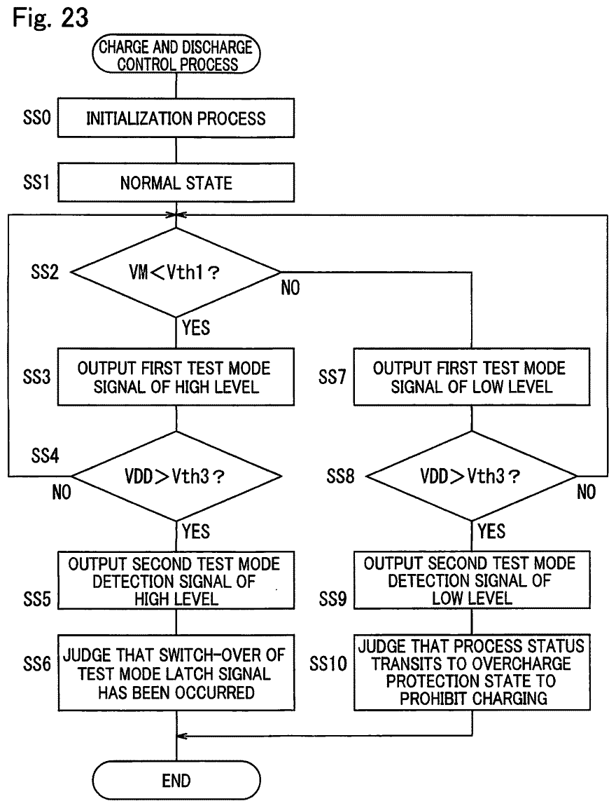

FIG. 23 is a flowchart showing charge and discharge control processing executed by the charge and discharge controller circuit 3E of FIG. 21.

Referring to FIG. 23, predetermined initialization processing is executed in step SS0. Next, in step SS1, a normal state is set, and charging and discharging are permitted. In step SS2, it is determined whether or not the terminal voltage VM of the terminal T14 is less than Vth1, and the processing proceeds to step SS3 if it is YES, whereas the processing proceeds to step SS7 if it is NO.

In step SS3, the high-level first test mode detection signal is output, the processing proceeds to step SS4, and it is determined whether the power supply voltage VDD>Vth3 is satisfied. If it is YES, the processing proceeds to step SS5, and if it is NO, the processing returns to step SS2. In step SS5, the high-level second test mode detection signal is output, and in step SS6, it is determined that the switching of the test mode latch signal has occurred, and the charge and discharge control processing ends.

In step SS7, the low-level first test mode detection signal is output, the processing proceeds to step SS8, and it is determined whether the power supply voltage VDD>Vth3 is satisfied. If it is YES, the processing proceeds to step SS9, and if it is NO, the processing returns to step SS2. In step SS9, the low-level second test mode detection signal is output, and in step SS10, it is determined that the state transitions to the overcharge protection state and charging is prohibited, and the charge and discharge control processing ends.

In the control flow of FIG. 23 configured as described above, for example, the threshold voltage Vth1 is −2 V and the threshold voltage Vth3 is 4.5 V.

### Effects of Embodiments

According to the first to sixth embodiments configured as described above, an arbitrary number of test modes can be selectively switched and designated using one test mode designation signal. That is, since the method is a method in which the test mode is switched and latched under two-stage requirements, it is possible to selectively switch to a plurality of test modes using only one test mode designation signal.

In addition, the conventional method also has the following problems.
(1) The combined logic circuit of the test mode may be likely to increase.
(2) An individually-optimal test mode entry method must be developed for analog semiconductor circuits having similar configurations.

On the other hand, the embodiments have the following functions and effects.
(1) The logic circuit that associates a test mode with a test function can be simply configured.
(2) The common test mode controller circuit and method can be used in an analog semiconductor circuit having many variations such as the charge and discharge controller circuit 3.

### Modified Embodiments

The above embodiments show examples of the embodiments according to the present disclosure, and do not limit the form of the disclosure.

The setting of the high level and the low level of each signal is an example, and the high level and the low level may be interchanged with each other as long as necessary information data can be transmitted.

Switching over between output and stop of each signal is an example, and the output and stop may be interchanged with each other as long as necessary information can be transmitted.

The counter circuit 13 and the shift register circuit 13A may be configured by a predetermined logic circuit without requiring the internal circuit to use a DFF or a TFF as long as necessary operation is possible.

There is no intention to limit the name of each terminal. For example, the power supply terminal is called a VCC terminal, a VIN terminal, or the like in addition to the VDD terminal.

Although the overdischarge protection and the short-circuit protection have been described as an example of the protection function in the abnormal state of the charge and discharge controller circuits 3 and 3A to 3D, the present disclosure is not limited thereto, and may have overcharge protection, discharge overcurrent protection, charge overcurrent protection, high-temperature temperature protection, low-temperature protection, and a state control function by external input.

Although the charge control transistor Q1 and the discharge control transistor Q2 are configured by CMOSFETs, the present disclosure is not limited thereto, and may be configured by other switch elements such as bipolar transistors.

The mode switching circuit according to the present embodiment is also applicable to a semiconductor device such as an LDO circuit or a DC-DC converter.

In the embodiment, the low-side configuration is used, but the present disclosure is not limited thereto, and the high-side configuration may be used. For example, in the low-side configuration, the VM voltage terminal T14 connected to the external negative electrode terminal T2 is provided, and the test mode detection requirement is determined based on the VM terminal voltage. However, in the high-side configuration, the VP terminal connected to the external positive electrode terminal T1 is provided, and the test mode detection requirement is determined based on the VP terminal voltage.

In the test mode detection requirement, in the VM terminal having the low-side configuration and the VP terminal having the high-side configuration, the movement of the voltage in the operation of the charge and discharge controller circuit is reversed in polarity. Therefore, the detection requirement that the VM terminal voltage is lower than the predetermined threshold in the low-side configuration is replaced with the detection requirement that the VP terminal voltage is higher than the predetermined threshold in the high-side configuration.

Further, in the present embodiment, the configuration in which the predetermined terminal voltage is simply compared with the predetermined threshold is disclosed as the first test mode detection requirement, but the present disclosure is not limited thereto, and the output of the first test mode detection signal may be started by setting the input of the predetermined one-pulse signal as the first test mode detection requirement. In this case, for example, the output of the first test mode detection signal may be stopped by inputting the one-pulse signal again.

The type and combination of terminals used for each test mode detection requirement described in the embodiment are merely examples, and may not be limited.

In the fifth and sixth embodiments, in the configuration in which the third test mode detection requirement is added, the second test mode detection requirement and the third test mode detection requirement are independent from each other. Therefore, the operation of switching the test mode latch signal when any one of the detection requirements is satisfied is similar to the configuration according to the first embodiment, and the configuration according to the first to fourth embodiments or the like may be applied to each of the second test mode detection requirement and the third test mode detection requirement.

When a predetermined threshold is set for each test mode detection requirement, the return requirement is not necessarily the same as the detection requirement, and for example, hysteresis may be provided. Specifically, the first test mode detection requirement may be configured such that the VM terminal voltage is set to, for example, −2 V or less, and the first test mode return requirement (condition for stopping the output of the detection signal) is configured such that the VM terminal voltage is set to, for example, −1 V or more.

For example, when the first, second, and third test mode detection requirements according to the fifth and sixth embodiments are all realized by one terminal, the test mode detection requirements and the return requirements can be set as follows.
(1) The first test mode detection requirement: VM is set to a negative voltage (for example, −5 V) or less.
(2) The first test mode return requirement: VM is set to a negative voltage (for example, −1 V) or more.
(3) The second test mode detection requirement: VM is set to a negative voltage (for example, −3 V) or more.
(4) The second test mode return requirement: VM is set to a negative voltage (for example, −3 V) or less.
(5) The third test mode detection requirement: VM is set to a negative voltage (for example, −8 V) or less.
(6) The third test mode return requirement: VM is set to a negative voltage (for example, −8 V) or more.

The second and third test mode control signals according to the fifth and sixth embodiments may be the same, and the data “0” and the data “1” to be written in the shift register circuit 13A may be distinguished from each other by the length of the pulse at the time of detection.
(1) The first test mode detection requirement: VM is set to a negative voltage (for example, −5 V) or less.
(2) The first test mode return requirement: VM is set to a negative voltage (for example, −1 V) or more.
(3) The second test mode detection requirement: VDD is set to (for example, 5 V) or more, and a return requirement is satisfied within 10 ms.
(4) The second test mode return requirement: VDD is set to (for example, 5 V) or less.
(5) The third test mode detection requirement: VDD is set to (for example, 5 V) or more, and a return requirement is satisfied after 20 ms or more has elapsed.
(6) The third test mode return requirement: VDD is set to (for example, 5 V) or less.

A plurality of first test mode detection requirements may be provided, and the test mode latch circuit to be used may be switched. For example, when the first test mode detection requirement A and the first test mode detection requirement B are provided, the test mode latch signal A may be switched when the second test mode detection requirement is satisfied after the first test mode detection requirement A is satisfied, and the test mode latch signal B may be switched when the second test mode detection requirement is satisfied after the first test mode detection requirement B is satisfied, That is, when any first test mode detection requirement is satisfied, the corresponding test mode latch signal is switched, and the present disclosure is naturally applied thereto.

In the above embodiment, an example of the terminal used in the charge and discharge controller circuit 3 and the like is shown, but the present disclosure is not limited thereto, and the terminal to be used is not limited thereto.

### Additional First Modified Embodiment

In the above embodiment, the time shortening mode or the internal voltage measurement mode is described as an example of the test function, but it is described that a specific bit of the test mode latch has a one-to-one correspondence with these test functions. The present disclosure is not limited thereto, and there are other coping methods and examples of other test functions and mode switching, which will be described below.

As described above, in the case of the control in which the signal of the specific bit of the test mode latch signal and the test function are simply associated one by one, the test mode controller circuit may be configured to output the input corresponding bit signal as it is, but as a method of controlling the test mode controller circuit, control may be performed such that combination logic (for example, logical product) is taken by the signals of a plurality of bits and the test function is switched by the output.

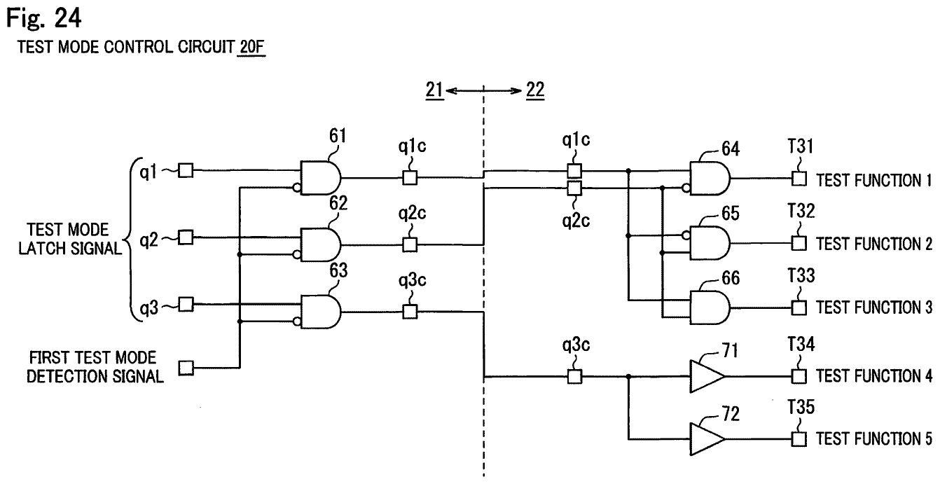

FIG. 24 is a block diagram showing a configuration example of a test mode controller circuit 20F which is a modified embodiment of the test mode controller circuit 20B of FIG. 10, the test mode controller circuit 20C of FIG. 13, the test mode controller circuit 20D of FIG. 16, and the test mode controller circuit 20E of FIG. 21.

The test mode controller circuit 20F of FIG. 24 includes two partial controller circuits 21 and 22 connected in cascade. In this case, the partial controller circuit 21 includes three AND gates 61, 62, and 63 with inverting inputs. In addition, the partial controller circuit 22 includes two AND gates 64 and 65 with inverting inputs, an AND gate 66, and two buffers 71 and 72. An example of the test mode controller circuit 20F in FIG. 24 is an example of any one of the test mode controller circuits 20B, 20C, 20D, and 20E according to the embodiment. In addition, since the test mode controller circuit 20 or 20A does not control enabling of the test function by the first test mode detection signal, the partial controller circuit 21 of FIG. 24 does not exist. When the output voltage q1c of the partial controller circuit 22 of FIG. 24 is replaced with q1, the output voltage q2c is replaced with q2, and the output voltage q3c is replaced with q3, an example of the test mode controller circuit 20 or 20A is obtained. Each of the buffers 71 and 72 is configured by, for example, two inverters connected in cascade.

In the partial controller circuit 21 of FIG. 24, the output voltages q1, q2, and q3 of the test mode latch signal are input to first input terminals of the AND gates 61, 62, and 63, respectively, and the first test mode detection signal is input to the second input terminals with inverted inputs of the AND gates 61, 62, and 63, respectively. The AND gates 61, 62, and 63 each execute an AND operation to respectively output the output voltages q1c, q2c, and q3c.

In the partial controller circuit 22 of FIG. 24, the output voltage q1c is input to a first input terminal of the AND gate 64, a first input terminal with an inverting input of the AND gate 65, and a first input terminal of the AND gate 66. In addition, the output voltage q2c is input to the second input terminal with inverting input of the AND gate 64, the second input terminal of the AND gate 65, and the second input terminal of the AND gate 66. The AND gate 64 executes an AND operation and outputs a signal instructing the test function 1 to the terminal T31. The AND gate 65 performs an AND operation and outputs a signal instructing the test function 2 to the terminal T32. The AND gate 66 performs an AND operation and outputs a signal instructing the test function 3 to the terminal T33. Further, the output voltage q3c is output to the terminal T34 via the buffer 71 to be a signal indicating the test function 4, and is output to the terminal T35 via the buffer 72 to be a signal indicating the test function 5.

In the partial controller circuit 22 configured as described above, the output voltages q1 to q3, which are third-bit input signals, are an example of the test mode latch signal. When the first test mode detection signal is output, the output voltages q1c to q2c of the AND gates 61 to 63 are fixed to low level regardless of the states of the output voltages q1 to q3. In this case, when the first test mode detection signal stops, the output voltages q1c to q3c of the AND gates 61 to 63 become equal to the output voltages q1 to q3. In this way, by configuring the selection of the test function corresponding to the test mode latch signal to be performed based on the output voltages q1c to q3c, the test mode controller circuit 20F does not enable the test function when the first test mode detection signal is output, and can enable the test function when the first test mode detection signal stops.

Further, the signal instructing the test functions 1 to 3 is the output of the AND gates 64 to 66, and its state is determined by the combination of the output voltages q1c and q2c as follows.
(1) When the output voltage q1c is at the high level and the output voltage q2c is at the low level, only the test function 1 is enabled.
(2) When the output voltage q1c is at the low level and the output voltage q2c is at the high level, only the test function 2 is enabled.
(3) When the output voltage q1c is at the high level and the output voltage q2c is at the high level, only the test function 3 is enabled.

With such a configuration, three types of test functions can be made to correspond to a combination of the output voltages q1 and q2 of the two-bit test mode latch signal and can be selectively enabled.

The state of the signal instructing the test function 4 and the signal instructing the test function 5 is determined in conjunction with the output voltage q3c. With such a configuration, a plurality of test functions can be made to correspond to the state of each test mode latch signal. That is, the predetermined at least one test function corresponding to the predetermined at least one logic calculation result based on the plurality of values of the test mode latch circuit can be set based on the test mode latch signal.

In the test mode controller circuit 20F of FIG. 24, an example in which the state of the first to third bit of the test mode latch signal corresponds to the enabling of the test functions 1 to 5 has been described. However, there are an infinite number of control methods for enabling the test function corresponding to the test mode latch signal, and the present disclosure is not limited to the method for associating the test mode latch signal and the test function in the test mode controller circuit.

In addition, what test function is enabled is not limited. Since the test function can be configured to affect arbitrary control of the entire charge and discharge controller circuit, although the operation is not explicitly illustrated and described in the description of each embodiment, there is no intention to limit the influence range and the control method of the test function.

### Additional Second Modified Embodiment

As an application example of the present disclosure, an example of a test function will be described with reference to an additional second modified embodiment.

A charge and discharge controller circuit according to the additional second modified embodiment is based on the charge and discharge controller circuit 3E of the sixth embodiment, and includes an overcharge detector circuit (second test mode detector circuit) 12D instead of the overcharge detector circuit (second test mode detector circuit) 12B. In this case, as an example of the test function and the mode switching, a function of only switching on and off of an internal switch of the charge and discharge controller circuit so as to correspond to a signal of each bit of the test mode latch signal will be described. Such a function may be used to finely adjust and assist target values of various protection functions such as an overcharge detection threshold voltage in a test process. For example, by turning on/off an internal switch, a trimming fuse for adjusting a target value of overcharge detection is virtually cut, and a finish after actually cutting by laser trimming is predicted, or the internal switch is combined with an OTP (One-Time Programmable) which is a technology for cutting a fuse at a high voltage or a high current in a test process and adjusting a target value. In this case, by turning on only the internal switch corresponding to the fuse to be blown, desired target value adjustment may be realized in the test process.

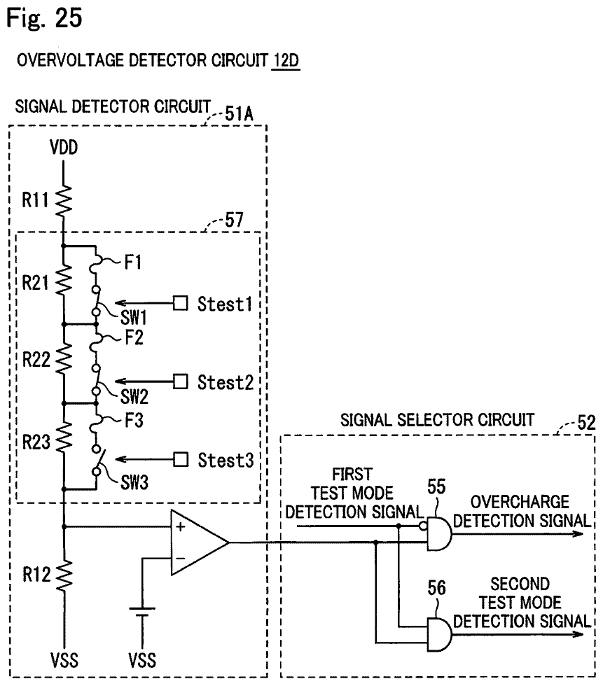

FIG. 25 is a block diagram showing a configuration example of an overcharge detector circuit 12D which is a modified embodiment of the overcharge detector circuit 12B of FIG. 22.

Referring to FIG. 25, the overcharge detector circuit 12D includes a signal detector circuit 51A and a signal selection circuit 52. In this case, the overcharge detector circuit 12D is characterized by further including a threshold adjustment circuit 57 between the resistor R11 and the resistor R12 with respect to the signal detector circuit 51.

Referring to FIG. 25, three resistors R21, R22, and R23 are connected in series, and are inserted and connected between the resistor R11 and the resistor R12. A series circuit of a trimming fuse F1 and a switch SW1 is connected in parallel with the resistor R21, a series circuit of a trimming fuse F2 and a switch SW2 is connected in parallel with the resistor R22, and a series circuit of a trimming fuse F3 and a switch SW3 is connected in parallel with the resistor R23. In this case, the switches SW1 to SW3 are constituted by semiconductor elements such as MOSFETs, for example.
(1) A test function 1 instruction signal is input to the control terminal of the switch SW1 from, for example, the tester apparatus 2 or another controller circuit. When the test function 1 instruction signal is at the high level, the switch SW1 is rendered non-conductive. When the test function I instruction signal is at the low level, the switch SW1 is rendered conductive.
(2) A test function 2 instruction signal is input to the control terminal of the switch SW2 from, for example, the tester apparatus 2 or another controller circuit. When the test function 2 instruction signal is at the high level, the switch SW2 is rendered non-conductive. When the test function 2 instruction signal is at the low level, the switch SW2 is rendered conductive.
(3) A test function 3 instruction signal is input to the control terminal of the switch SW3 from, for example, the tester apparatus 2 or another controller circuit. When the test function 3 instruction signal is at the high level, the switch SW3 is rendered non-conductive. When the test function 3 instruction signal is at the low level, the switch SW3 is rendered conductive.

The signal detector circuit 51A including the threshold adjustment circuit 57 configured as described above includes:
(A) the voltage-dividing resistors R11 and R12 that divide a voltage formed by the internal reference voltage VSS and the power supply voltage VDD; and
(B) a variable resistance circuit including the resistors R21 to R23, the trimming fuses F1 to F3, and the switches SW1 to SW3.

The comparator 54 compares the voltage resistance-divided by the voltage-dividing resistors R11 and R12 and adjusted by the variable resistance circuit with the reference voltage of the reference voltage source 53, and outputs a comparison result signal.

Note that it is assumed that each state of the test functions 1 to 3 has already been determined by any of the methods described in the first to sixth embodiments, for example, and the description of the method of selecting the test function will be omitted.

In this case, when the test functions 1 to 3 are not enabled, the corresponding switches SW1 to SW3 are conductive, and when the trimming fuses F1 to F3 are also conductive, the corresponding resistors R21 to R23 do not contribute to voltage division, respectively, In addition, when the test functions 1 to 3 are enabled, the corresponding switches SW1 to SW3 are non-conductive, and even if the trimming fuses F1 to F3 are conductive, the corresponding resistors R21 to R23 each contribute to voltage division.

The trimming fuses F1 to F3 can be switched between a conductive state and a non-conductive state by thermally cutting only a designated fuse using, for example, a laser trimming apparatus in a test process of a charge and discharge controller circuit, and are used for the purpose of adjusting thresholds for detection of various protection functions with high accuracy, However, the cutting of the trimming fuses F1 to F3 is irreversible, and it is difficult to readjust when misalignment occurs after the cutting of the trimming fuses F1 to F3.

In addition, the switches SW1 to SW3 can switch between a conductive state and a non-conductive state by enabling a test function in a test process of the charge and discharge controller circuit, and can reproduce a state electrically equivalent to a state after the trimming fuses F1 to F3 are cut without actually cutting the trimming fuses F1 to F3, for example. With such a configuration, due to variations in the resistance values of the resistors R21 to R23 and the like, it is possible to grasp in advance the deviation of the threshold values for the detection of various protection states (overcharge protection in the additional second modified embodiment) that occurs after the trimming fuses F1 to F3 are cut. Since the trimming fuses F1 to F3 to be actually cut can be determined based on the information, the threshold can be adjusted with higher accuracy.

As described above in detail, according to the test mode controller circuit of the present disclosure, an arbitrary number of test modes can be selectively switched and designated using one test mode designation signal.

What is claimed is:

1. A test mode controller circuit comprising:
a first test mode detector circuit detecting a first test mode based on a. terminal voltage of a first terminal, and outputting a first test mode detection signal;
a second test mode detector circuit detecting a second test mode based on a terminal voltage of a second terminal in response to the first test mode detection signal, and outputting a second test mode detection signal;
a test mode latch circuit outputting a test mode latch signal having a predetermined value in response to the second test mode detection signal; and
a controller configured to set a predetermined test function corresponding to a value of the test mode latch circuit based on the test mode latch signal.

2. The test mode controller circuit as claimed in claim 1,
wherein the test mode latch circuit outputs test mode latch signals having different values upon each output of the second test mode detection signal.

3. The test mode controller circuit as claimed in claim 1,
wherein the first terminal and the second terminal are identical to each other.

4. The test mode controller circuit as claimed in claim 1,
wherein, based on a change in a value of the test mode latch signal, the controller does not set a test function corresponding to the value of the test mode latch signal in a time interval in which the first test mode detection signal is output, and sets the test function corresponding to the value of the test mode latch signal when the output of the first test mode detection signal is stopped.

5. The test mode controller circuit as claimed in claim 1,
wherein the test mode latch circuit initializes a value of the test mode latch circuit based on the first test mode detection signal.

6. The test mode controller circuit as claimed in claim 1, further comprising a third test mode detector circuit detecting a third test mode based on a terminal voltage of a third terminal in response to the first test mode detection signal, and outputting a third test mode detection signal,
wherein the test mode latch circuit outputs a test mode latch signal having a predetermined value in response to the second test mode detection signal and the third test mode detection signal.

7. The test mode controller circuit as claimed in claim 6,
wherein the second terminal and the third terminal are identical to each other.

8. The test mode controller circuit as claimed in claim 1,
wherein the controller sets one predetermined test function corresponding to one value of the test mode latch circuit based on the test mode latch signal.

9. The test mode controller circuit as claimed in claim 1,
wherein the controller sets a plurality of predetermined test functions corresponding to a plurality of values of the test mode latch circuit, respectively, based on the test mode latch signal.

10. The test mode controller circuit as claimed in claim 1,
wherein the controller sets at least one predetermined test function corresponding to at least one predetermined logic calculation result based on a plurality of values of the test mode latch circuit based on the test mode latch signal.

11. The test mode controller circuit as claimed in claim 1,
wherein the second test mode detector circuit detects a second test mode by comparing a terminal voltage of a second terminal with a predetermined threshold and outputs a second test mode detection signal in response to the first test mode detection signal, and
wherein the second test mode detector circuit further comprises a threshold adjustment circuit that adjusts the threshold.

12. A charge and discharge controller circuit for controlling discharge from a secondary battery to a load or charge from a charger to the secondary battery, the charge and discharge controller circuit comprising:
a test mode controller circuit,
wherein the test mode controller circuit comprises:
a first test mode detector circuit detecting a first test mode based on a terminal voltage of a first terminal, and outputting a first test mode detection signal;
a second test mode detector circuit detecting a second test mode based on a terminal voltage of a second terminal in response to the first test mode detection signal, and outputting a second test mode detection signal;
a test mode latch circuit outputting a test mode latch signal having a predetermined value in response to the second test mode detection signal; and
a controller configured to set a predetermined test function corresponding to a value of the test mode latch circuit based on the test mode latch signal,
wherein the controller is configured to set a test function of the charge and discharge controller circuit.

13. A battery apparatus comprising:
a secondary battery;
a charge and discharge controller circuit configured to discharge from a secondary battery to a load or change from a charger to the secondary battery,
wherein the charge and discharge controller circuit comprises:
a test mode controller circuit,
wherein the test mode controller circuit comprises:
a first test mode detector circuit detecting a first test mode based on a terminal voltage of a first terminal, and outputting a first test mode detection signal;
a second test mode detector circuit detecting a second test mode based on a terminal voltage of a second terminal in response to the first test mode detection signal, and outputting a second test mode detection signal;
a test mode latch circuit outputting a test mode latch signal having a predetermined value in response to the second test mode detection signal; and
a controller configured to set a predetermined test function corresponding to a value of the test mode latch circuit based on the test mode latch signal,
wherein the controller is configured to set a test function of the charge and discharge controller circuit,
wherein the battery apparatus further comprises:
a charge control switch element that controls the charge based on a charge control signal from the charge and discharge controller circuit; and
a discharge control switch element that controls the discharge based on a discharge control signal from the charge and discharge controller circuit.

14. A test mode control method comprising the steps of:
detecting, by a first test mode detector circuit, a first test mode based on a terminal voltage of a first terminal, and outputting a first test mode detection signal;
detecting, by a second test mode detector circuit, a second test mode based on a terminal voltage of a second terminal in response to the first test mode detection signal, and outputting a second test mode detection signal;
outputting, by a test mode latch circuit, a test mode latch signal having a predetermined value in response to the second test mode detection signal; and
setting, by a controller, a predetermined test function corresponding to a value of the test mode latch circuit based on the test mode latch signal.

15. The test mode control method as claimed in claim 14, further comprising a step of:
detecting, by a third test mode detector circuit, a third test mode based on a terminal voltage of a third terminal in response to the first test mode detection signal, and outputting a third test mode detection signal,
wherein outputting the test mode latch signal includes outputting a test mode latch signal having a predetermined value in response to the second test mode detection signal and the third test mode detection signal.

16. The test mode control method as claimed in claim 14,
wherein setting the predetermined test function includes the controller setting one predetermined test function corresponding to one value of the test mode latch circuit based on the test mode latch signal.

17. The test mode control method as claimed in claim 14,
wherein setting the predetermined test function includes the controller setting a plurality of predetermined test functions corresponding to a plurality of values of the test mode latch circuit, respectively, based on the test mode latch signal.

18. The test mode control method as claimed in claim 14,
wherein setting the predetermined test function includes setting, by the controller, at least one predetermined test function corresponding to at least one predetermined logic calculation result based on a plurality of values of the test mode latch circuit based on the test mode latch signal.

19. The test mode control method as claimed in claim 14,
wherein outputting the second test mode detection signal further includes a step of detecting, by the second test mode detector circuit, a second test mode by comparing a terminal voltage of a second terminal with a predetermined threshold in response to the first test mode detection signal, and outputting a second test mode detection signal, and adjusting, by the second test mode detector circuit, the threshold.
